(19) United States
(12) Patent Application Publication
(10) Pub. No.: US 2022/0311452 A1
(43) Pub. Date: Sep. 29, 2022

(54) DEVICE AND METHOD FOR REDUCING FEEDBACK OVERHEAD ASSOCIATED WITH BITMAP REPORTING

(71) Applicant: NTT DOCOMO, INC., Tokyo (JP)

(72) Inventors: Nadisanka Rupasinghe, Tokyo (JP); Haralabos Papadopoulos, Tokyo (JP)

(73) Assignee: NTT DOCOMO, INC., Tokyo (JP)

(21) Appl. No.: 17/610,904

(22) PCT Filed: Jun. 10, 2019
(86) PCT No.: PCT/US2019/036331

§ 371 Date: Nov. 12, 2021

Related U.S. Application Data
(60) Provisional application No. 62/846,898, filed on May 13, 2019.

(51) Int. Cl. H03M 7/40; H03M 7/42; H04L 1/00; H04L 5/00; H04B 7/06

(52) U.S. Cl. CPC H03M 7/4037; H03M 7/42; H04L 1/0014; H04L 1/0016; H04L 1/003; H04L 5/0057; H04B 7/0626; H04B 7/0636

(57) ABSTRACT

A method for reducing feedback overhead associated with bitmap reporting may be implemented between a user equipment and a base station. The method includes activating a coding scheme for reporting a bitmap in association with a prefix coding scheme, encoding a plurality of bit groups using the prefix coding scheme, generating a plurality of codeword sets for the plurality of bit groups, and reporting the codeword sets generated.

### CROSS-REFERENCE TO RELATED APPLICATIONS

This application claims priority to U.S. Provisional Patent Application Ser. No. 62/846,898, titled “Efficient Coding Scheme for Bitmap Reporting in Rel.16 Type II CSI,” which was filed on May 13, 2019, and is incorporated herein by reference in its entirety.

### TECHNICAL FIELD

One or more embodiments disclosed herein relate to a device and a method for reducing feedback overhead associated with bitmap reporting.

### BACKGROUND

New Radio (NR) supports Type II CSI feedback for rank 1 and rank 2. In the Type II CSI feedback, an amplitude scaling mode is configured.

In the amplitude scaling mode, a user equipment (UE) may be configured to report a wideband (WB) amplitude with a subband (SB) amplitudes and SB phase information. In the conventional scheme, considerable fraction of the total overhead may be occupied by overhead for the SB amplitude and phase reporting. Consider the SB precoder generation in NR Rel.15 Type II CSI for single layer transmission.

W=W_{space}W_{coeff} (1)

Here, the matrix W (Nₜ×N_{SB}) captures precoding vectors for N_{SB} sub-bands. Note that Nₜ denotes the number of available TXRU ports. W_{space} (Nₜ×2L) consists of the 2L wideband spatial 2D-DFT beams. The matrix capturing the SB combination coefficients is represented in (1) by W_{coeff} Those SB amplitude and phase information needs to be reported are in W_{coeff}. As discussed, reporting this information will occupy large portion of the feedback overhead and hence it is necessary somehow compress this information.

One way to achieve this is through the time domain compression. The following describes how time domain compression can be incorporated here. Let U={set of selected 2D-DFT spatial beams}. Now, the u^{th} row w_{coeff}^{u} of W_{coeff} which captures the complex combination coefficient associated with u^{th} (∈U) spatial beam can be given as,

w_{coeff}^{u}=[c₁^{u}c₂^{u} . . . c_{N}_{_{SB}}^{u}] (2)

where ciu, i∈{1, . . . , N_{SB}} is the combination coefficient for i^{th} sub-band of u^{th} spatial beam. Note here that, (2) captures frequency domain channel representation of the u^{th} spatial beam. Since the beam focuses the energy to a particular direction, intuitively it can be understood that there will be few scatterers within the channel. As a result, if the time domain representation of the channel corresponding to u^{th} spatial beam is considered, there will be few significant taps in the channel impulse response. If these significant taps can be identified properly and fed back to the gNB, frequency domain channel can be almost accurately regenerated at the gNB. This way the time domain compression can reduce feedback overhead associated with W_{coeff} by reporting the information of significant channel taps. Number of significant taps to report may differ based on the approach considered for detecting significant taps in the channel impulse response.

### CITATION LIST

### Non-Patent Reference

[Non-Patent Reference 1] 3GPP TS 38.214 (V15.3.0), “NR; Physical layer procedures for data”, October, 2018
[Non-Patent Reference 2] 3GPP RAN #82, RP-182863, “Revised WID: Enhancements on MIMO for NR”, December, 2018
[Non-Patent Reference 3] 3GPP RAN1 #95, “RAN1 Chairman's Notes”, November, 2018
[Non-Patent Reference 4] 3GPP RAN #96, R1-1902811, “Type II CSI feedback enhancement”, February, 2019
[Non-Patent Reference 5] 3GPP RAN1 Meeting #96, “RAN1 Chairman's Notes”, February, 2019
[Non-Patent Reference 6] 3GPP RAN1 #96b, “RAN1 Chairman's Notes”, April, 2019

### SUMMARY

In one or more embodiments, a method for reducing feedback overhead associated with bitmap reporting between a user equipment and a base station. The method includes activating a coding scheme for reporting a bitmap in association with a prefix coding scheme. The method includes encoding a plurality of bit groups using the prefix coding scheme. The method includes generating codeword sets for the plurality of bit groups. The method includes reporting the codeword sets generated.

In one or more embodiments, the method includes dividing the bitmap into a plurality of bit groups, each bit group corresponding to a unique information value in the bitmap. The method includes obtaining a probability value relating to at least one codeword set out of the codeword sets generated. The method includes using the probability value for selecting the at least one codeword set. The method includes using the at least one codeword set for encoding at least one bit group using the prefix coding scheme.

In one or more embodiments, the method uses the at least one codeword set for encoding at least one bit group using the prefix coding scheme.

In one or more embodiments, the method includes, in generating the plurality of codeword sets based on the probability value of the at least one codeword set, bit groups with a higher probability value are coded with smaller size codewords

In one or more embodiments, the method includes assuming separate codeword sets for each probability value are predefined.

In one or more embodiments, the method includes assuming separate codeword sets for each probability value are predefined based on different bit group information parameters.

In one or more embodiments, the method includes obtaining a codeword information parameter associated to at least one bit group. The method includes obtaining a probability value of at least one codeword set based on the codeword information parameter. The method includes determining parameters for encoding the plurality of bit groups using the prefix coding scheme based on the probability value for the at least one codeword set. The method includes feeding back information indicative of the parameters for encoding the plurality of bit groups.

In one or more embodiments, the method includes the codeword information parameter associated to at least one bit group is a number indicative of an amount of Non-Zero Coefficients (NZC) in the bitmap.

In one or more embodiments, includes creating a bitmap-to-codeword mapping table. The method includes encoding the plurality of bit groups using the bitmap-to-codeword mapping table created.

In one or more embodiments, the method includes the bitmap-to-codeword mapping table used is rank-dependent.

In one or more embodiments, the method includes the bitmap-to-codeword mapping table used is common to all ranks.

In one or more embodiments, the method includes creating at least two bitmap-to-codeword mapping tables. The method includes encoding the plurality of bit groups using the at least two bitmap-to-codeword mapping tables created. The method includes reporting the codeword sets generated preceded by a preamble indicator, the preamble indicator indicating which table out of the at least two bitmap-to-codeword mapping tables is being used.

In one or more embodiments, the method includes the prefix coding scheme is a Huffman coding scheme. The method includes the feedback overhead associated with bitmap reporting is performed in association with performing Channel State Information (CSI) feedback in a wireless communication system.

In one or more embodiments, the method includes identifying Non-Zero Coefficients (NZCs) for at least one layer. The method includes obtaining locations for the NZCs identified. The method includes determining a number of NZCs. The method includes creating the bitmap capturing the NZCs locations obtained and the number of NZCs.

In one or more embodiments, the method includes evaluating a plurality of bitmaps for a plurality of layers. the method includes determining a size of a joint bitmap, the joint bitmap comprising the plurality of bitmaps for the plurality of layers. The method includes creating the joint bit map comprising the plurality of bitmaps for the plurality of layers. The method includes the joint bitmap comprising at least one probability value relating to selecting one or more codeword sets.

In one or more embodiments, the method includes the at least one probability value is determined from evaluating the joint bit.

In one or more embodiments, a user equipment includes a receiver that receives bitmap information from a base station. The user equipment includes a processor that activates a coding scheme for reporting a bitmap based on the bitmap information received and in association with a prefix coding scheme, encodes a plurality of bit groups using the prefix coding scheme, generates codeword sets for the plurality of bit groups. The user equipment includes a transmitter that transmits the codeword sets generated.

In one or more embodiments, a method for reducing feedback overhead associated with bitmap reporting between a user equipment and a base station includes generating, by the base station, a bitmap information, the bitmap information includes predetermined information relating to at least one code scheme. The method includes selecting, by the user equipment, a rank associated with a bitmap size and a number of Non-Zero Coefficients (NZCs), the rank and the number of NZCs being selected using the bitmap information. The method includes identifying a code scheme for encoding a bitmap based on the rank and the number of NZCs selected. The method includes encoding, by the user equipment, the bitmap using the code scheme identified. The method includes feeding back, by the user equipment, the rank and the number of NZCs selected to the base station. The method includes decoding, by the base station, the encoded bitmap using the code scheme used by the user equipment, which is identified by the rank and the number of NZCs fed back by the user equipment.

Advantageously, the proposed FD compression techniques provide a user equipment (UE) that performs feedback transmission of a bitmap which identifies exact locations of non-zero combination coefficients and reduces feedback overheads associated with Rel. 15 Type II CSI, which are identified to be high. This bitmap consists of 1s and 0s, with 1s indicating the locations of non-zero combination coefficients. Furthermore, because the number of 0s and 1s in the bitmap are unequally distributed, probabilities of 1s and 0s in the bitmap can be quantified considering some pre-configured parameters. Those probabilities can then be used along with a Huffman coding scheme to design an efficient coding scheme for bitmap reporting, which is information theoretically with achieving the Entropy.

Other aspects of the disclosure will be apparent from the following description and the appended claims.

### BRIEF DESCRIPTION OF THE DRAWINGS

FIG. 1 is a diagram showing a configuration of a wireless communication system according to one or more embodiments of the present invention.

FIG. 2 is a diagram showing a layer configuration according to one or more embodiments of the present invention.

FIG. 3 shows an example in accordance with one or more embodiments.

FIG. 4 shows an example in accordance with one or more embodiments.

FIG. 5 shows an example in accordance with one or more embodiments.

FIG. 6 shows an example in accordance with one or more embodiments.

FIG. 7 shows an example in accordance with one or more embodiments.

FIG. 8 shows an example in accordance with one or more embodiments.

FIG. 9 shows an example in accordance with one or more embodiments.

FIG. 10 shows an example in accordance with one or more embodiments.

FIG. 11 shows an example in accordance with one or more embodiments.

FIG. 12 shows an example in accordance with one or more embodiments.

FIG. 13 shows a sequence diagram showing an operation in a wireless communication system according to one or more embodiments of the present invention.

FIG. 14 shows a block diagram of an assembly in accordance with one or more embodiments.

FIG. 15 shows a block diagram of an assembly in accordance with one or more embodiments.

### DETAILED DESCRIPTION

Specific embodiments of the invention will now be described in detail with reference to the accompanying figures. Like elements in the various figures are denoted by like reference numerals for consistency.

In the following detailed description of embodiments of the invention, numerous specific details are set forth in order to provide a more thorough understanding of the invention. However, it will be apparent to one of ordinary skill in the art that the invention may be practiced without these specific details. In other instances, well-known features have not been described in detail to avoid unnecessarily complicating the description.

Throughout the application, ordinal numbers (e.g., first, second, third, etc.) may be used as an adjective for an element (i.e., any noun in the application). The use of ordinal numbers is not to imply or create any particular ordering of the elements nor to limit any element to being a single element unless expressly disclosed, such as by the use of the terms “before”, “after”, “single”, and other such terminology. Rather, the use of ordinal numbers is to distinguish between the elements. By way of an example, a first element is distinct from a second element, and the first element may encompass more than one element and succeed (or precede) the second element in an ordering of elements.

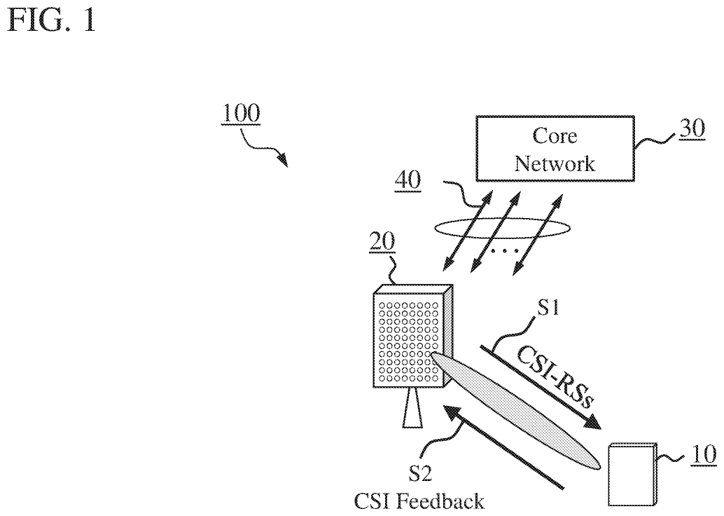

A wireless communication system 100 according to one or more embodiments of the present invention will be described below with reference to FIG. 1.

As shown in FIG. 1, the wireless communication system 100 includes a User Equipment (UE) 10, a Base Station (BS) 20, and a core network 30. The wireless communication system 100 may be an New Radio (NR) system or a Long Term Evolution (LTE)/LTE-Advanced (LTE-A) system.

The BS 20 communicates with the UE 10 via multiple antenna ports using a multiple-input and multiple-output (MIMO) technology. The BS 20 may be gNodeB (gNB) or Evolved NodeB (eNB). The BS 20 receives downlink packets from a network equipment such as upper nodes or servers connected on the core network 30 via the access gateway apparatus, and transmits the downlink packets to the UE 10 via the multiple antenna ports. The BS 20 receives uplink packets from the UE 10 and transmits the uplink packets to the network equipment via the multiple antenna ports.

The BS 20 includes antennas for MIMO to transmit radio signals between the UE 10, a communication interface to communicate with an adjacent BS 20 (for example, X2 interface), a communication interface to communicate with the core network (for example, S1 interface), and a CPU (Central Processing Unit) such as a processor or a circuit to process transmitted and received signals with the UE 10. Functions and processing of the BS 20 described below may be implemented by the processor processing or executing data and programs stored in a memory. However, the BS 20 is not limited to the hardware configuration set forth above and may include any appropriate hardware configurations. Generally, a plurality of the BSs 20 may be disposed so as to cover a broader service area of the wireless communication system 1.

The UE 10 communicates with the BS 20 using the MIMO technology. The UE 10 transmits and receives radio signals such as data signals and control signals between the BS 20 and the UE 10. The UE 10 may be a mobile station, a smartphone, a cellular phone, a tablet, a mobile router, or information processing apparatus having a radio communication function such as a wearable device.

The UE 10 includes a CPU such as a processor, a RAM (Random Access Memory), a flash memory, and a radio communication device to transmit/receive radio signals to/from the BS 20 and the UE 10. For example, functions and processing of the UE 10 described below may be implemented by the CPU processing or executing data and programs stored in a memory. The UE 10 is not limited to the hardware configuration set forth above and may be configured with, e.g., a circuit to achieve the processing described below.

The wireless communication 1 supports Type II CSI feedback. As shown in FIG. 1, at step S1, the BS 20 transmits CSI-Reference Signals (RSs). When the UE 10 receives the CSI-RSs from the BS 20, the UE 10 performs measurements of the received CSI-RSs. Then, at step S2, the UE 10 performs CSI reporting to notify the BS 20 of the CSI as CSI feedback. For example, the CSI includes at least one of rank indicator (RI), precoding matrix index (PMI), channel quality information (CQI), CSI-RS resource indicator (CRI), a wideband (WB) amplitude, a subband (SB) amplitude, and a SB phase. In one or more embodiments of the present invention, the CSI reporting that reports the SB amplitude may be referred to as SB amplitude reporting. For example, rather than reporting the SB amplitude every time when the CSI reporting takes place, the periodicity of reporting the SB amplitude may be dynamically adjusted using higher layer signaling from the BS 20. The SB amplitude reporting may be performed for K leading coefficients. For example, if K is small, the number of coefficients reporting SB amplitudes is small.

If the SB amplitudes are significantly small compared to an amplitude of the strongest coefficient, achievable gains with SB amplitude reporting may be marginal. That may occur when a user channel is highly sparse in an environment with very few scatterers, for example.

Furthermore, in one or more embodiments, while Type II CSI feedback may allow layer handling up to layers with RI of 1 and 2, by altering the scheme, Type II CSI feedback may also be implemented in ranks greater than 2. As such, by extending Type II CSI feedback scheme for rank >2, spectral efficiency can be further enhanced. Extending the Type II CSI feedback scheme to ranks greater than 2 may reduce the overhead generally associated with the scheme.

To this point and as indicated above, Type II CSI precoding vector generation for N₃ precoding matrix indicator (PMI) sub-bands (SBs) considering RI=v, layer l∈{1, 2, . . . v} transmission may be evaluated expanding on rule (2). For example,

Wᵢ(Nₜ×N₃)=W_{1,l}W_{coeff,l} (3)

In the above equation, W_{1,l}(Nₜ×2L) may be a matrix consisting of L SD 2D-DFT basis for layer l, L may be a Beam number, Nₜ may be a Number of ports, and W_{coeff,l}(2L×N₃) may be an SB complex combination coefficient matrix for layer l.

In the above equations, SD 2D-DFT basis subset may be given as {b_{l,1}, . . . b_{l,L}} where b_{l,i} may be an i-th (∈{1, . . . L}) 2D DFT basis vector corresponding to an l-th layer.

In one or more embodiments, frequency domain compression must be accounted for as information within W_{coeff,l} may be compressed. As such, corresponding overhead may be further reduced. For example, Type II CSI precoding vectors of layer l for N_{sg} sub-bands (SBs) considering FD compression can be given by expanding W_{coeff,l} from rule (3).

Wᵢ(Nₜ×N_{SB})=W_{1,l} [symbol] W_{freq,l}^{H} (4)

In the above equation, W_{freq,l}(N₃×M) may be a matrix consisting of M FD DFT basis vectors for layer l and \tilde{W}ₗ(2L×M) may be a matrix consisting of complex combination coefficients for layer l. Furthermore, frequency domain DFT basis subset may be given as {f_{l,1}, . . . f_{l,M}} where f_{l,i} may be i-th (∈{1, . . . , M}) DFT basis vector corresponding to the 1-th layer. Additionally, M may be calculated as,

$$M = ⌈ p \times \frac{{N}_{3}}{R} ⌉$$

where R∈{1,2} in a way that, M depends on p and if p may be known M can be determined. As such, given L and p, SD and FD basis subsets for layer l can be identified.

In one or more embodiments, in order to achieve a proper balance between performance and overhead, SD and FD bases may be identified across layers appropriately.

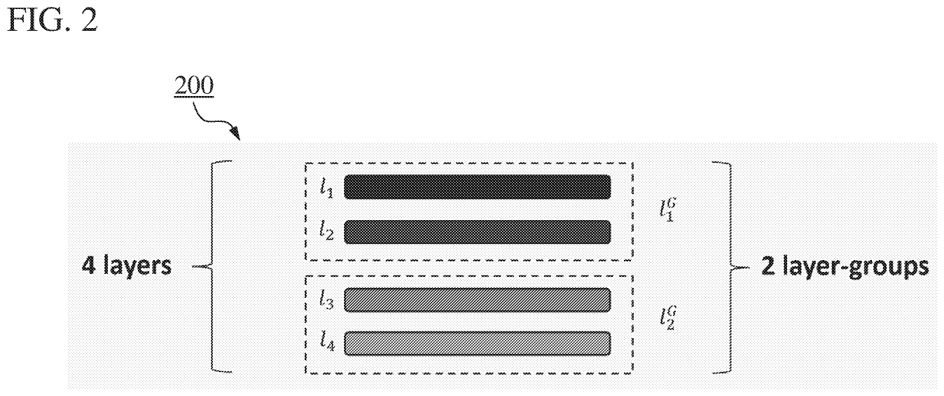

FIG. 2 may be a diagram 200 showing an example arrangement of layers and layer groups according to one or more embodiments. Specifically, in a case where a RI equals 4, and a number of layer groups equals 2, the values of beam number and scaling factor may be implemented for various layers, a group of layers, or specific layers. As such, it may be possible to assign (L, p) across layers/layer groups and to identify SD/FD basis subsets, given (L, p) across layers/layer-groups for RI∈{3,4}.

In one or more embodiments, for RI∈{3,4}, SD and FD basis selection may be achieved based on how (L, p) may be identified. For example, in a case where (L, p) may be common for various layers in a given rank, RI=v, letting L=L₁ and p=p₁, then various layers may select SD basis subset consisting of L₁ 2 D DFT basis vectors and FD basis subset consisting of p₁ DFT basis vectors. This may be called a common layer assigning.

In one or more embodiments, for RI∈{3,4}, SD and FD basis selection may be achieved based on how (L, p) may be identified. For example, in a case where (L, p) may be layer-group-specific in a given rank, RI=v, grouping together available layers and letting a number of layer-groups be G(v), then a g^{th} layer-group, l_{g}^{G} may be assigned for (L_{g}, p₉), g∈{1,2, . . . G} with L_{g} 2D DFT basis vectors (SD subset) and p_{g} DFT basis vectors (FD subset). This may be called a group-specific assigning. Specifically, in group-specific assigning, there may be no restriction to assign layer-group-common L or p (for SD or FD basis subsets respectively) while the other one with layer-group-specific assignment.

As such, in one or more embodiments, for SD basis subset, L_{g}, g∈{1,2, . . . G} may be layer-group-common, L_{g}_{₁}=L_{g}_{₂} with g₁, g₂∈{1,2, . . . G} and g₁≠g₂ while for FD basis subset p_{g}, g∈{1,2, . . . G} may be layer-group specific. Thus, assigning may not be restricted to having single layer groups, (i.e., G=v either for SD or FD basis selection or for both). This may be called layer-specific assignment.

In one or more embodiments, the configurations described above may follow common layer, group-specific, and layer-specific configurations. In the case of common layer configuration, for (L, p), the UE may assume L and/or p to be configured by higher layer parameters. If the UE is not configured with values of L and/or p, the UE may consider pre-determined values for L and/or p.

Similarly, the UE may assume a set of values for L and/or p to be configured by higher layer parameters, and the UE may assume that one value for L and/or p of the set may be as indicated by x-bit(s) DCI or by using higher layer signaling. In such event, the UE may be informed which value to use as (2-1) x is specified (e.g. x=2) and (2-2) x may be flexible depending on the number of values per one set, which may be configured by higher layer signaling. For example, if 4 value per set may be configured, the UE assumes 2 bits in DCI; if 8 values per set may be configured, UE assumes 3 bits in DCI.

Furthermore, the UE may assume a set of values for L and/or p may be pre-determined, and the UE may assume that one value of the set for L and/or p as indicated by x-bit(s) DCI, where (3-1) x may be specified (e.g. x=2).

In the case of group or layer-specific configuration, the UE may assume {L₁, . . . L_{G}} and/or {p₁, . . . p_{G}}, to be configured by higher layer parameters. If the UE may not be configured with values of {L₁, . . . L_{G}} and {p₁, . . . p_{G}}, then the UE may consider pre-determined values for {L₁, . . . L_{G}} and {p₁, . . . p_{G}}. Similarly, the UE may assume that value sets for {L₁, . . . L_{G}} and {p₁, . . . p_{G}} may be configured by higher layer parameters, and the UE may assume at least one value set for {L₁, . . . L_{G}} and {p₁, . . . p_{G}} as indicated by x-bit(s) DCI or using higher layer signaling. In which case, the UE may be informed which value to use given that (2-1) x may be specified (e.g., x=2) and (2-2) x may be flexible depending on the number of values per one set, which may be configured by higher layer signaling (e.g., if 4 value sets may be configured, UE assumes 2 bits in DCI; if 8 value sets may be configured, UE assumes 3 bits in DCI). Furthermore, the UE may assume that at least a value set for{L₁, . . . L_{G}} and {p₁, . . . p_{G}} may be pre-determined. As such, the UE may assume one value set out of those sets as indicated by x-bit(s) DCI (3-1) x may be specified (e.g., x=2).

In one or more embodiments, basis subsets may be selected. Selecting basis subsets may also be divided into common layer, group-specific, and layer-specific configurations. As such, in a case where the configuration may be common layer, to identify SD and FD basis subsets, the following options can be considered.

Opt.1: Common SD basis and common FD basis. In this case, various layers in RI=v, a common 2D DFT SD basis subset may be selected. Hence, {b_{l,1}, . . . b_{l,L}} may be the same for ∀l∈{1,2, . . . v}. Furthermore, for various layers in RI=v, a common FD basis subset may be selected. Hence, {f_{l,1}, . . . f_{l,M}} may be the same for ∀l∈{1,2, . . . v}.

Opt.2: Common SD basis and independent FD basis. In this case, various layers in RI=v, a common 2D DFT SD basis subset may be selected. Hence, {b_{i,1}, . . . b_{i,L}} may be the same for ℄l∈{1, 2, . . . v}. Furthermore, independent FD basis subsets may be selected by different layers. Hence, {fₗ_{₁}_{,1}, . . . fₗ_{₁}_{,L}}≠{fₗ_{₂}_{,1}, . . . fₗ_{₂}_{,M}} with l₁, l₂∈{1, 2, . . . v} and l₁≠l₂.

Opt.3: Independent SD basis and Common FD basis. In this case, independent SD basis subsets may be selected by different layers. Hence, {bₗ_{₁}_{,i}, . . . bₗ_{₁}_{,L}}≠{bₗ_{₂}_{,1}, . . . bₗ_{₂}_{,L}} with l₁, l₂∈{1, 2, . . . v} and l₁≠l₂. Furthermore, for various layers L in RI=v, a common FD basis subset may be selected. Hence, {f_{l,1}, . . . f_{l,M}} may be the same for ∀l∈{1, 2, . . . v}.

Opt.4: Independent SD basis and independent FD basis. In this case, independent SD basis subsets may be selected by different layers. Hence, {bₗ_{₁}_{,1}, . . . bₗ_{₁}_{,L}}≠{bₗ_{₂}_{,1}, . . . bₗ_{₂}_{,L}} with l₁, l₂∈{1, 2, . . . v} and l₁≠l₂. Furthermore, independent FD basis subsets may be selected by different layers. Hence, {fₗ_{₁}_{,1}, . . . fₗ_{₁}_{,M}}≠{fₗ_{₂}_{,1}, . . . fₗ_{₂}_{,M}} with l₁, l₂∈{1, 2, . . . v} and l₁≠l₂.

In view of the above, in one or more embodiments, some of the following advantages may be perceived in common layer configurations. Such advantages may include less feedback overhead since SD and FD basis subsets may be common for various layers and better performance since SD and FD basis subsets may be layer specific. Furthermore, the UE may provide a better balance between feedback overhead and performance compared to other options.

Kayer and group specific configurations may perceive similar advantages. As such, to identify SD basis subset in group-specific configuration, the following options may be considered for SD basis subset selection.

Opt.1: Independent SD basis subsets may be selected by different layer-groups. In this case, {bₗ_{₁}_{^{G}}_{,1}, . . . bₗ_{₁}_{^{G}}_{,L}_{₁}}≠{bₗ_{₂}_{^{G}}_{,1}, . . . , bₗ_{₂}_{^{G}}_{,L}_{₂}} with l₁^{G}, l₂^{G}∈E {1, 2, . . . G} and l₁^{G}≠l₂^{G}. If L_{g}, g∈{1, 2, . . . G} may be a common layer-group, then different layer-groups will have different SD basis subsets with the same cardinality.

Opt.2: For various layer-groups G(≤v) in RI=v, 2D DFT SD basis subsets may be selected from a common subset of 2D DFT beams. The cardinality of this subset may be, Lₘₐₓ=max{L₁ . . . L_{G}} For example, let layer-group lₘₐₓ^{G} be assigned with Lₘₐₓ and the corresponding SD basis subset being [symbol] _{L}={bₗ_{ₘₐₓ}_{^{G}}_{,1}, . . . , bₗ_{ₘₐₓ}_{^{G}}_{,L}_{ₘₐₓ}}. Then, layer-group lᵢ^{G}∈{1, 2, . . . G}\lₘₐₓ^{G} will have a SD basis which may be a subset of [symbol] _{L}.

The following options may be considered for FD basis subset selection.

Opt.1: Independent FD basis subsets are selected by different layer-groups. In this case, {fₗ_{₁}_{^{G}}_{,1}, . . . fₗ_{₁}_{^{G}}_{,M}_{₁}}≠{fₗ_{₂}_{^{G}}_{,1}, . . . fₗ_{₂}_{^{G}}_{,M}_{₂}} with l₁^{G}, l₂^{G}∈{1, 2, . . . g} and l₁^{G}≠l₂^{G}. If M_{g}, g∈{1, 2, . . . G} may be a common layer-group, then different layer-groups will have different FD basis subsets with the same cardinality.

Opt.2: For various layer-groups G(≤v) in RI=v, DFT FD basis subsets are selected from a common subset of DFT beams. The cardinality of this subset may be, Mₘₐₓ=max{M₁ . . . M_{G}}. For example, letting layer-group lₘₐₓ^{G} being assigned with Mₘₐₓ and the corresponding FD basis subset may be [symbol] _{M}={fₗ_{ₘₐₓ}_{^{G}}_{,L}_{₁}, . . . fₗ_{ₘₐₓ}_{^{G}}_{,L}_{ₘₐₓ}}. Then, layer-group lᵢ^{G}∈{1, 2, . . . G}\lₘₐₓ^{G} will have a FD basis which may be a subset of [symbol] ₘ. Subsequently, if M_{g}, g∈{1, 2, . . . G} may be layer-group-common, [symbol] _{M} may be the same for various layer-groups.

Advantageously, the above configurations provide better performance since SD and FD basis subsets are layer-group specific. Additionally, less feedback overhead may be required since SD and/or FD basis subsets may be selected from a smaller subset of the original set.

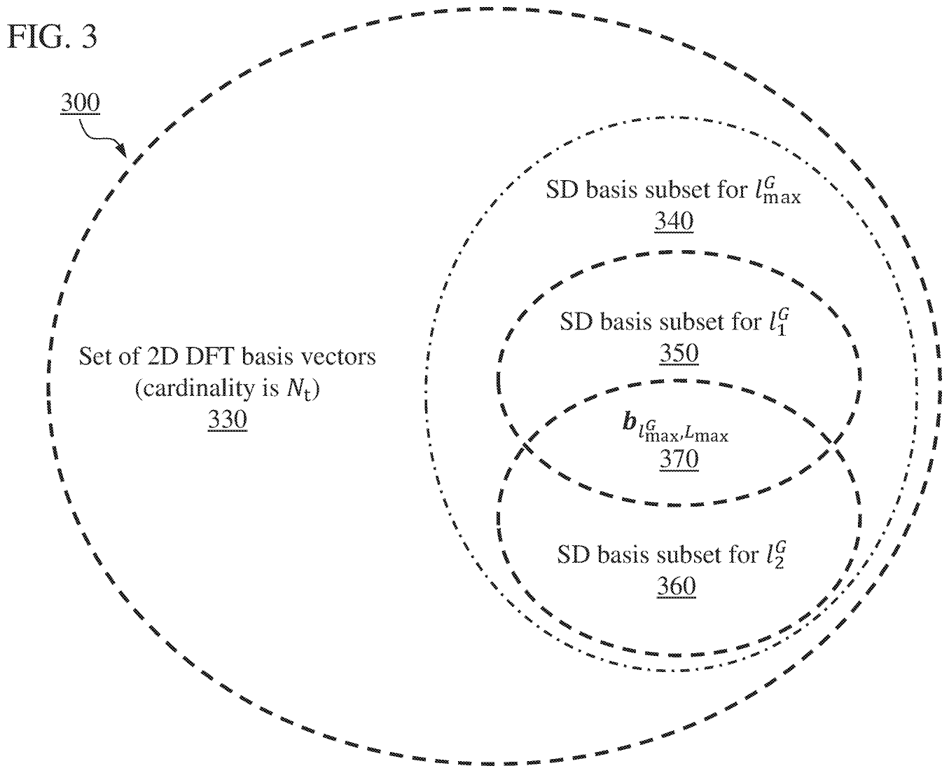

FIG. 3 is an example according to one or more embodiments. Specifically, FIG. 3 shows set representation of possible SD basis subsets for layer-groups 340-360. As mentioned above, if L_{g} may be layer-group-common 370, with rule (4), the same SD basis subset will be assigned for various layer-groups 330.

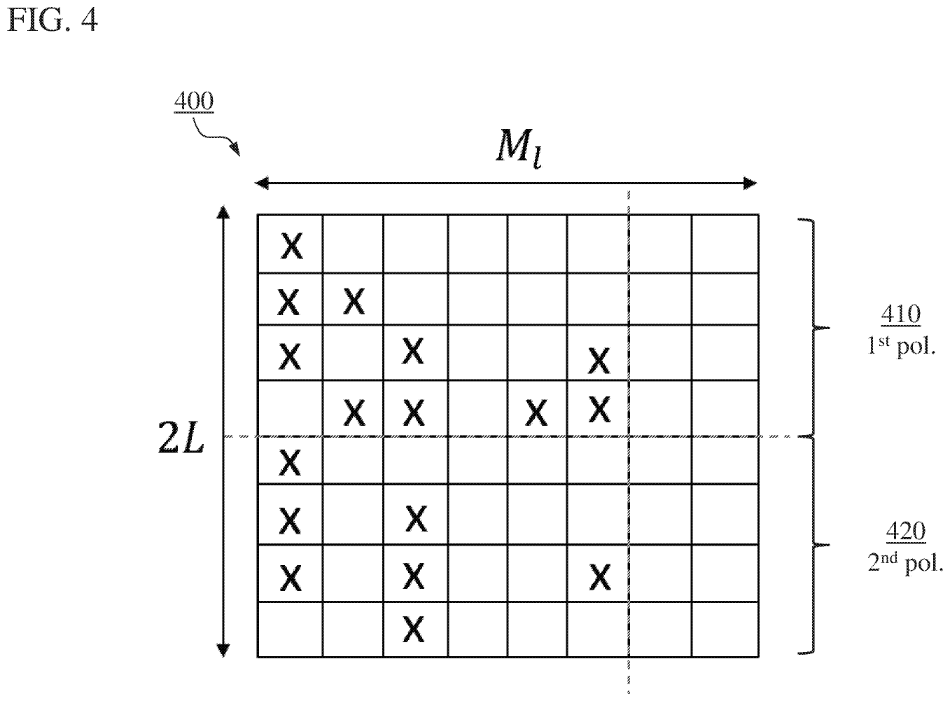

FIG. 4 is an example according to one or more embodiments.

Specifically, FIG. 4 shows NZC distribution 400 for a layer L. The representation includes a bitmap capturing NZC locations 410 and 420 and Quantized NZC. In such, case, overheads associated with bitmap reporting may be considered high. As discussed above, SD basis size may be the same for various layers 410 and 420. For example, size of spatial domain (SD) DFT basis (RI=1, 2, 3, 4), L=2, 4. Size of FD DFT basis per layer (RI=1, 2),

$$M = ⌈ p \times \frac{{N}_{3}}{R} ⌉ ,$$

where

$$p ∈ \{ \frac{1}{4} , \frac{1}{2} \}$$

### and R∈{1, 2}.

Furthermore, the table follows the rule that a maximum number of NZCs per layer may be (RI=1, 2), where K₀=┌β×2LM┐ and

$$β ∈ \{ \frac{1}{4} , \frac{1}{2} \} .$$

As such, total NZC across various layers (RI=3, 4)≈2K₀. Similarly to SD, FD basis size may be the same for various layers. For example, with Alt3C (L, p) selection (RI=3, 4). As such, when reporting NZC of an l-th layer, reporting may include a bitmap capturing NZC locations and a number of NZCs in the table. Further, the FD basis size may be the same for all layers.

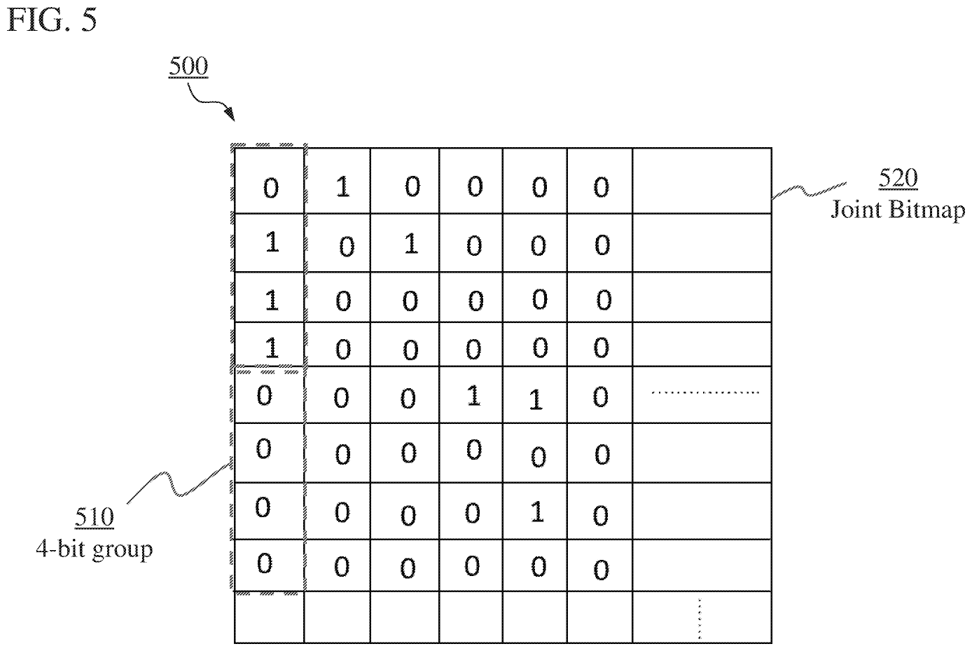

FIG. 5 is an example according to one or more embodiments. Specifically, FIG. 5 shows an example of a coding scheme for bitmap reporting 500. Considering bitmaps of various layers, a joint bitmap can be created. In FIG. 5, Let rank, RI=v. Then, based on current agreement that Σᵢ₌₀^{v-1}Mᵢ≅2M and M may be FD basis size per layer for RI=1, 2 size of the joint bitmap 520, such that,

$${B}_{T o t} = 2 L {\sum }_{i = 0}^{v - 1} {M}_{i} \qquad ( 5 )$$

Additionally, in the example of FIG. 5, bit groups to be encoded with Huffman coding may be then generated by grouping set of bits. Size of such a bit group may be determined as,

$$Number of bits / group = ⌈ \frac{{B}_{T o t}}{2 {K}_{0}} ⌉ \qquad ( 6 )$$

Probability of “1” in the joint bitmap may be, for example,

$$P \{ y = 1 \} = \frac{2 {K}_{0}}{{B}_{Tot}} \qquad ( 7 )$$

Probability of “0” in the joint bitmap may be, for example,

$$P \{ y = 0 \} = \frac{{B}_{Tot} - 2 {K}_{0}}{{B}_{Tot}} \qquad ( 8 )$$

That is, the example may not be restricted to consider single layer bitmap and apply proposed coding scheme. In the Example itself, let L=4, Bₗₒₜ=224, K₀=28 and v=4. As such

$$P \{ y = 1 \} = \frac{56}{224} = 0.25 , \\ P \{ y = 0 \} = \frac{168}{224} = 0.75 ,$$

Number of bits/group=4 (with 16 different bit groups), and Entropy=3.24 bits because Entropy,

$$H ( X ) = \sum {p}_{i} log 1 / {p}_{i} = \frac{81}{256} log \frac{256}{81} + 4 \times \frac{27}{256} log \frac{256}{27} + 6 \times \frac{9}{256} log \frac{256}{9} + 4 \times \frac{3}{256} log \frac{256}{3} + \frac{1}{256} log \frac{256}{1} = 3.24 bits .$$

As such, compressed bitmaps may be on average as short as 3.24×28=90.72 bits long for the example. Further, different codeword sets may be generated considering P{y=1}=⅛, 1/16, or more.

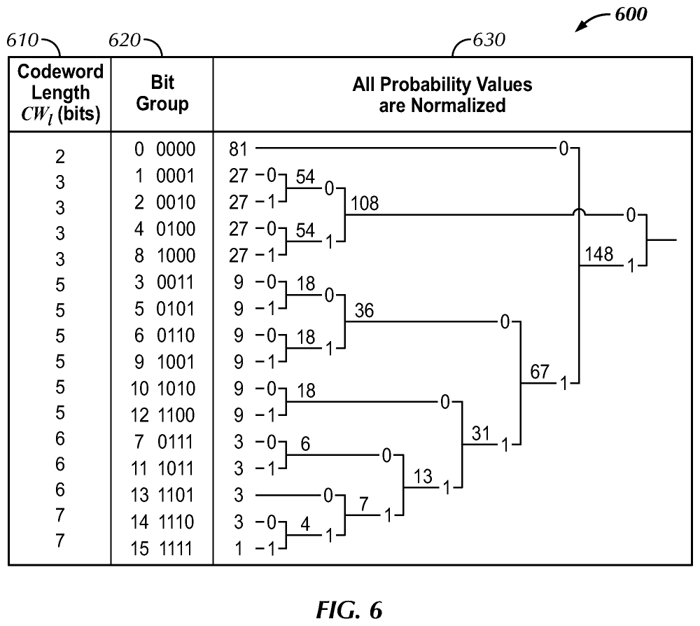

FIG. 6 is an example according to one or more embodiments. Specifically, FIG. 6 shows the relation between code word length CWᵢ (in bits) 610 and the designated bit group 620. In this case, the coding scheme 600 relies on Huffman coding to branch out and deduce the binary grid for the bitmap, in which values may be divided (in this case, divided by 256) and split as they branch out.

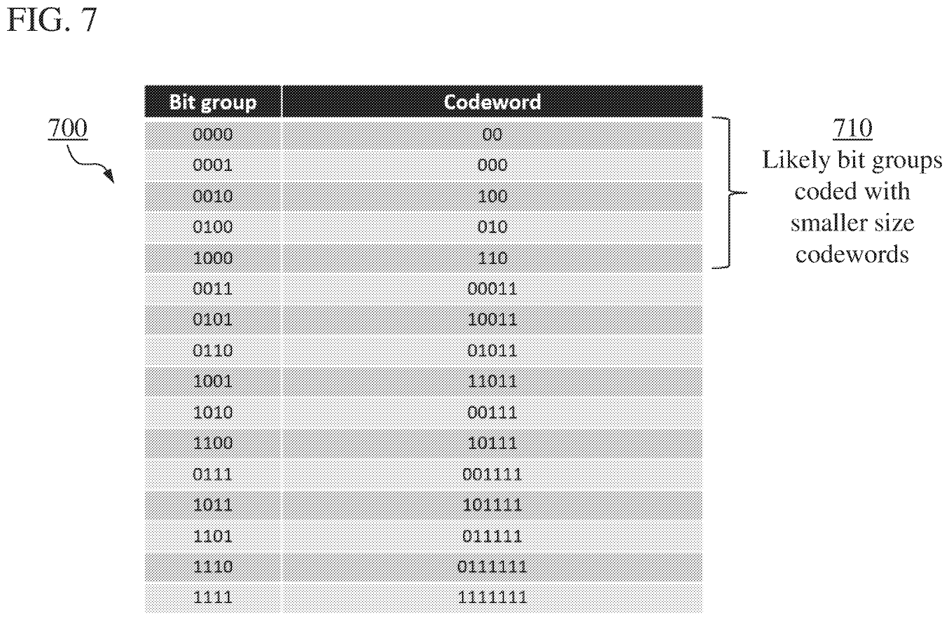

FIG. 7 is an example according to one or more embodiments. Specifically, FIG. 7 shows a codeword mapping table 700 showing allocation of a bit group. As shown in the table 700, bit groups with a higher probability may be encoded with smaller size words and bit groups with a lower probability may be encoded with bigger size words. Size may be an information parameter that could be determined before creating the bitmap. As such, the information parameter may be predetermined before the codeword sets may be generated.

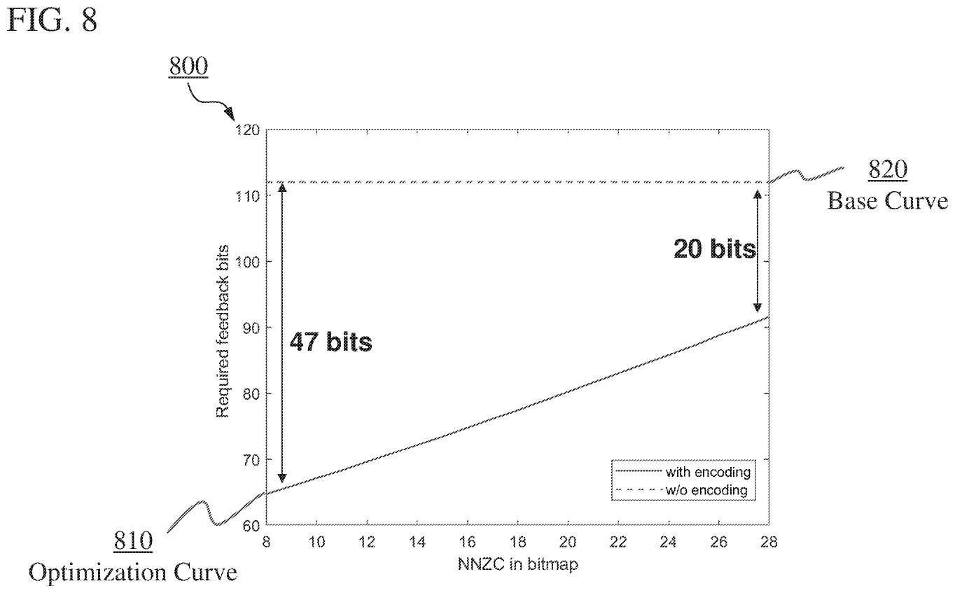

FIG. 8 is an example according to one or more embodiments. Specifically, FIG. 8 shows an example analysis of feedback overhead with encoding. As shown in Bitmap Encoding Graph 800, required feedback bits may be compared between an optimization curve 810 and a base curve 820. The optimization curve 810 may be a representation of bits reduced from the base amount of bits, as represented by the base curve 820.

Furthermore, as shown in FIG. 8, a total amount of bits may be 112 bits, a number of total non-zero coefficients (NZC) across all layers may be 28 bits, and the codeword set may be encoded for a probability value of P{y=1}=¼. In this case, with a single codeword set, overhead may be reduced by 20 bits even when NNZC=2K₀ (worst case).

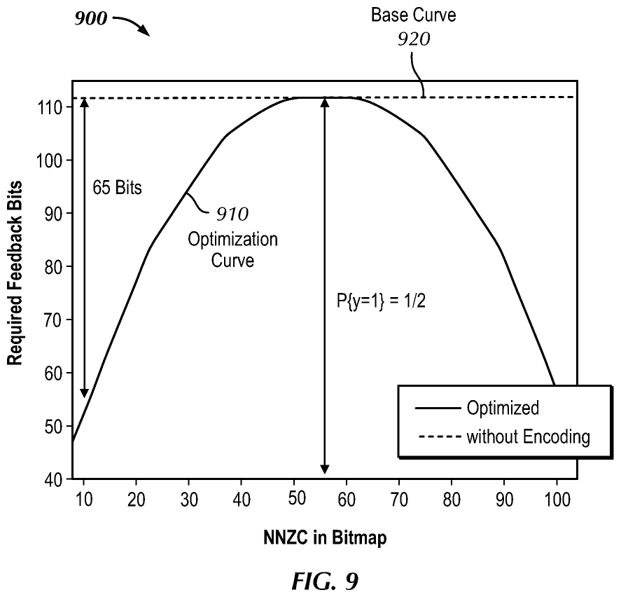

FIG. 9 is an example according to one or more embodiments.

Specifically, FIG. 9 shows codeword sets designed for every possible NNZC. As shown in Bitmap Encoding Graph 900, required feedback bits may be compared between an optimization curve 910 and a base curve 920. The optimization curve 910 may be a representation of bits reduced from the base amount of bits, as represented by the base curve 820.

Furthermore, as shown in FIG. 9, the same codeword set used in FIG. 8 may be used to encode bitmaps with different NNZCs. As such, a level of optimization may be maintained by using probability value optimized for several other codeword sets. For example, codeword sets may be optimized for each NNZC. As shown in FIG. 9, 97 different codeword sets may be used to encode a same bitmap. Such an encoding can provide maximum overhead reduction for bitmap reporting. Since NNZC is also reported, the compression scheme used is implicitly specified by the reported NNZC value.

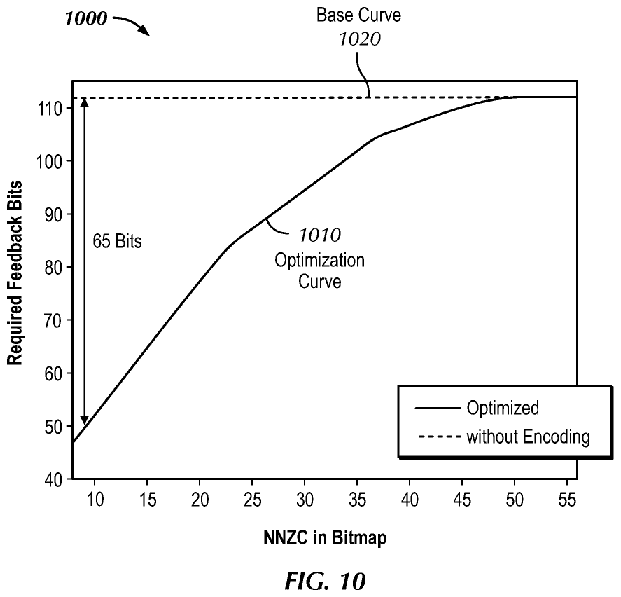

FIG. 10 is an example according to one or more embodiments. Specifically, FIG. 10 shows codeword sets designed for half of the possible NNZC. As shown in Bitmap Encoding Graph 1000, required feedback bits may be compared between an optimization curve 1010 and a base curve 1020. The optimization curve 1110 may be a representation of bits reduced from the base amount of bits, as represented by the base curve 1020.

Furthermore, as shown in FIG. 10, the same codeword set used in FIG. 8 and FIG. 9 may be used to encode bitmaps with different NNZCs. As such, a level of optimization may be maintained by using probability value optimized for several other codeword sets. For example, feedback overhead of optimized codeword design is symmetric around P{y=1}=½. In this case,

$$\{ y = 1 \} = \frac{k}{{B}_{T o t}} \\ and \\ P \{ y = 0 \} = \frac{{B}_{T o t} - k}{{B}_{T o t}}$$

when k<B_{Tot}/2 switches when NNZC>B_{Tot}/2. This allows reusing codeword sets designed when P{y=1}≤½ for P{y=1}≥½. As such, a codeword set designed for P{y=1}=x may be used for P{y=0}=x. In the example, bit analysis and encoding in the bitmap may switch from ‘0’ to ‘1’ and ‘1’ to ‘0’ when reusing such a codeword set. Further, by looking at NNZC values, any mobile device in the network may understand whether bit switching is applied or not.

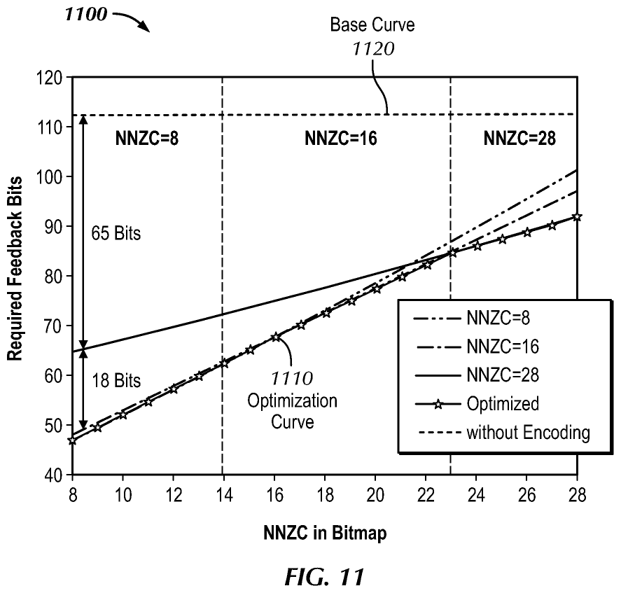

FIG. 11 is an example according to one or more embodiments. Specifically, FIG. 11 shows codeword sets designed for few NNZCs. As shown in Bitmap Encoding Graph 1100, required feedback bits may be compared between an optimization curve 1110 and a base curve 1120. The optimization curve 1110 may be a representation of bits reduced from the base amount of bits, as represented by the base curve 1120.

Furthermore, as shown in FIG. 11, the same codeword set used in FIG. 8, FIG. 9, and FIG. 10 may be used to encode bitmaps with different NNZCs. As such, a level of optimization may be maintained by using probability value optimized for several other codeword sets. For example, rather than using one coding scheme per NNZC value, a subset of these coding schemes corresponding to a subset of NNZC values may be used and still achieve optimized compression performance. Such is the case of the example of FIG. 8, 3 codeword sets for NNZC={8, 16, 28} can provide optimized performance at different NNZC ranges. As such, when encoding, a mobile terminal may select an appropriate codeword set based on NNZC. For Example, by looking at NNZCs in the UE, the BS may understand the respective codeword set.

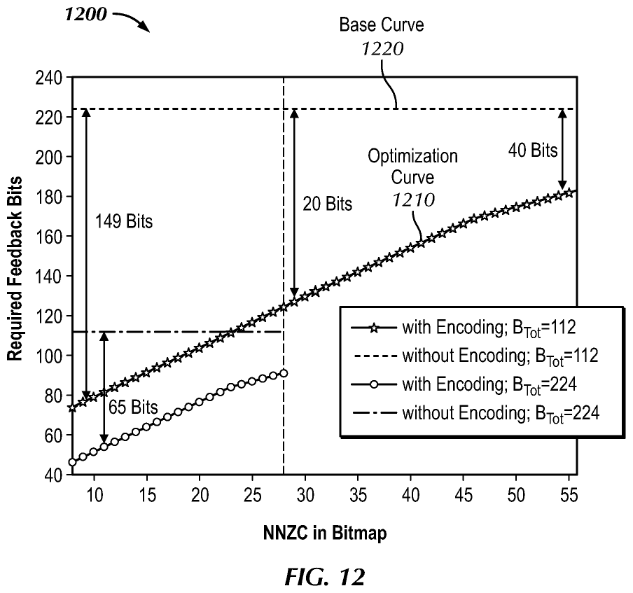

FIG. 12 is an example according to one or more embodiments. Specifically, FIG. 12 shows codeword sets designed for large bitmap sizes. As shown in Bitmap Encoding Graph 1200, required feedback bits may be compared between an optimization curve 1210 and a base curve 1220. The optimization curve 1210 may be a representation of bits reduced from the base amount of bits, as represented by the base curve 1220.

As shown in FIG. 12, the bit optimization for the bitmaps may be expanded to cover several times more bits. Expanding this coverage may be implemented by escalating the encoding process. As such, in a larger bitmap size, more overhead savings may be achieved with encoding performed by a coding scheme.

For example, encoding and decoding a bitmap of size 40 bits with the proposed scheme may include an uncompressed bitmap of 0000010000010000000100000010000100001000 that may be further separated in bit nibbles to obtain 0000|0100|0001|0000|0001|0000|0010|0001|0000|1000. In this case, the UE may be configured by a codeword mapping rule with a bit group of 26 bits. These bits may be 01010000010000110000001110 and based on codeword probability, it may be divided to match the nibbles from the bitmap as 01|010|000|01|000|01|100|000|01|110, where the nibbles correspond to the divided codeword mapping rule of the UE. As such, the BS may uniquely decode the compressed bit map without relying on extra parameters or additional information.

Furthermore, in an event where the uncompressed bitmap includes more ‘1’s than ‘0’s, the bit map may be switched to obtain the analysis with reference to ‘0’s. As such, any bit may be compressed and encoded based on their respective maximum number of ‘0’s or ‘1’s. This may be referred to as a codeword information parameter (codeword probability value) for a unique information value (‘0’s or ‘1’s).

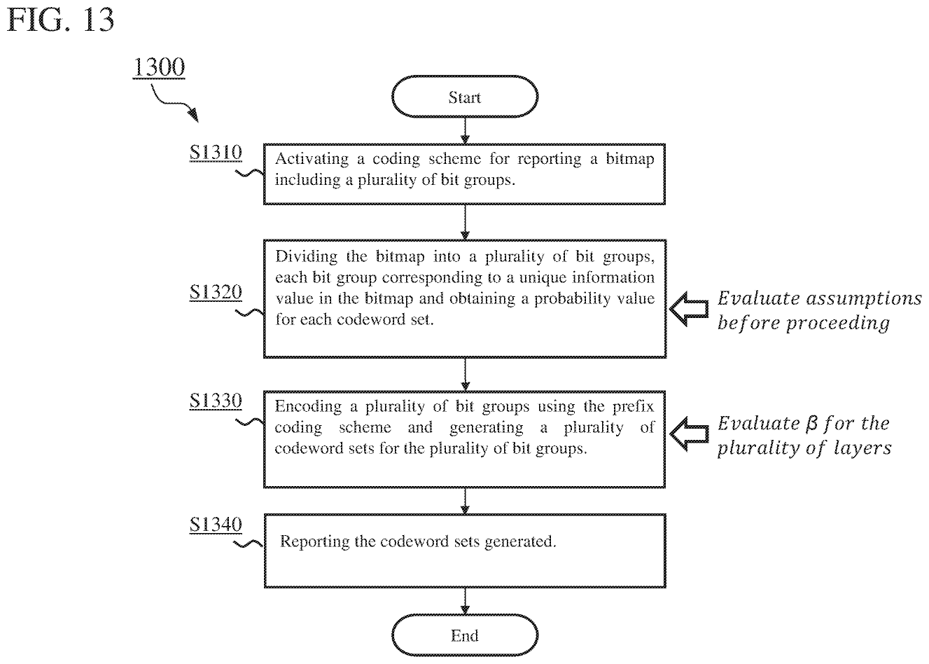

FIG. 13 shows a flowchart in accordance with one or more embodiments. Specifically, FIG. 13 describes a method 800 for reducing feedback overhead associated with bitmap reporting between a user equipment and a base station. One or more blocks in FIG. 13 may be performed by one or more components as described above in FIGS. 1-12. While the various blocks in FIG. 13 are presented and described sequentially, one of ordinary skill in the art will appreciate that some or various of the blocks may be executed in different orders, may be combined or omitted, and some or various of the blocks may be executed in parallel. Furthermore, the blocks may be performed actively or passively.

In Block S1310, a coding scheme for reporting a bitmap in association with a Huffman coding scheme in a plurality of bit groups may be initiated. The Huffman coding scheme being started by the UE or triggered by the BS based on a technique for reducing overhead. The Huffman coding scheme including creating a binary tree of nodes, the binary tree of nodes being stored in a regular array, the size of which depends on a number of symbols N. A node from the tree being either a leaf node or an internal node.

In one or more embodiments, various initial nodes may be leaf nodes, which contain the symbol itself, the weight (i.e., frequency of appearance or a probability value) of the symbol and optionally, a link to a parent node forms from a leaf node. Internal nodes contain a weight, links to two child nodes and an optional link to a parent node. As a common convention, bit “0” represents following the left child and bit “1” represents following the right child. A finished tree has up to “N” leaf nodes and “N−1” internal nodes. A Huffman tree that omits unused symbols produces the reduced code lengths.

In Block 51320, the bitmap may be divided into a plurality of bit groups, each bit group corresponding to a unique information value in the bitmap, and probability values may be obtained for each bit group generated based on the bit groups encoded. One probability value, average or raw, may be obtained for at least one bit group and in the present method. The probability values may be values obtained from frequency patterns identified in a specific bit group. In one or more embodiments, an average frequency may be used as a determining factor to evaluate the probability values. Specifically, the probability value may be an average frequency for a unique value information in the bitmap.

Furthermore, the Huffman coding scheme omits unused symbols in encoding, which greatly reduces providing feedback with respect to unused symbols. At this point, several assumptions come into play to determine whether codeword sets may be created from the encoded bit groups. That is, codeword sets may be determined by evaluating certain assumptions. These assumptions may be: (i) assuming separate sets of codewords for each β may be defined in the specification; (ii) assuming separate sets of codewords may be defined in the specification considering different bit group sizes; (iii) assuming that codeword sets must be derived; and (iv) assuming that sets of codewords may be configured by higher layer signaling.

In Block 51330, the UE encodes each bit group out of the plurality of bit groups using their respective probability value and generating a plurality of codeword sets for the plurality of bit groups. This process may be heavily dependent on the result from the assumptions described above. Specifically, with respect to assumptions (i), (ii), and (iv).

With respect to (i), the UE assumes several sets of codewords for each β may be defined in the specification. In (i), BS informs UE which codeword set to select using DCI or higher layer signaling. As such, this can be achieved as indicated by x-bit(s) DCI or using higher layer signaling. This assumption requires “x” to be specified in the specification (e.g., x=2).

With respect to (ii), the UE assumes several sets of codewords for different bit group sizes may be defined in the specification. In (ii), BS informs UE which codeword set to select using DCI or higher layer signaling. As such, this can be achieved as indicated by x-bit(s) DCI or using higher layer signaling, and this assumption requires “x” may be specified in the specification (e.g., x=2).

With respect to (iv), the UE assumes several sets of codewords may be configured by higher layer signaling. In (iv), using x-bit(s) DCI, UE may be informed which set of codewords to consider. This assumption requires “x” may be specified in the specification (e.g., x=2).

In Block S1340, the codeword sets generated may be reported. Specifically, the codeword sets may be reported after obtaining a bit group size for each bit group out of the plurality of bit groups, calculating the probability value of each bit group out of the plurality of bit groups, and determining probability value locations in the codeword sets. In one or more embodiments, the codeword sets may be reported after identifying NZCs for a layer L, obtaining locations for the NZCs identified, quantizing the NZCs, and reporting the codeword sets capturing the NZCs locations and the quantized NZC.

In one or more embodiments, codeword sets may be reported including information of a joint bitmap after evaluating a plurality of bitmaps for a plurality of layers M, determining a size of the joint bitmap based on an Entropy relation, creating the joint bit map comprising the plurality of bitmaps for the plurality of layers M; and the joint bitmap comprising the probability value of each bit group out of the plurality of bit groups. In this case, the Entropy relation may be that an expected codeword length for a codeword out of a plurality of codewords may be the same as the Entropy in bits, the Entropy relation may be defined by the equation

$$H ( x ) = \sum {p}_{i} log ( \frac{1}{{p}_{i}} ) ,$$

and an Entropy H(x) may be a weighted sum, in bits, across various symbols pi with non-zero probability of the information content of each symbol.

In one or more embodiments, the method described in FIG. 8 may be used for reducing feedback overhead associated with bitmap reporting. Specifically, if a number of 1s in the joint bitmap may be 2K₀ or less, the proposed coding scheme results in strictly lower overhead than bitmap reporting without Huffman coding scheme. That may be, codeword sets may be determined based on different β values as the proposed scheme yields a compressed bitmap representation. Similarly, bit group sizes may be determined based on 1/β.

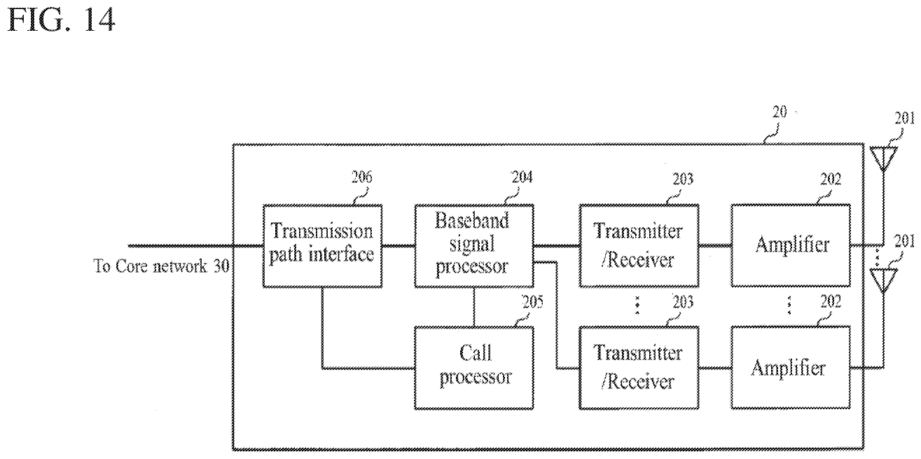

The BS 20 according to one or more embodiments of the present invention will be described below with reference to the FIG. 14.

As shown in FIG. 14, the BS 20 may comprise an antenna 201 for 3D MIMO, an amplifier 202, a transmitter/receiver circuit 203 (hereinafter referred as including a CSI-RS scheduler), a baseband signal processor 204 (hereinafter referred as including a CS-RS generator), a call processor 205, and a transmission path interface 206. The transmitter/receiver 202 includes a transmitter and a receiver.

The antenna 201 may comprise a multi-dimensional antenna that includes multiple antenna elements such as a 2D antenna (planar antenna) or a 3D antenna such as antennas arranged in a cylindrical shape or antennas arranged in a cube. The antenna 201 includes antenna ports having one or more antenna elements. The beam transmitted from each of the antenna ports may be controlled to perform 3D MIMO communication with the UE 10.

The antenna 201 allows the number of antenna elements to be easily increased compared with linear array antenna. MIMO transmission using a large number of antenna elements may be expected to further improve system performance. For example, with the 3D beamforming, high beamforming gain may be also expected according to an increase in the number of antennas. Furthermore, MIMO transmission may be also advantageous in terms of interference reduction, for example, by null point control of beams, and effects such as interference rejection among users in multi-user MIMO can be expected.

The amplifier 202 generates input signals to the antenna 201 and performs reception processing of output signals from the antenna 201.

The transmitter included in the transmitter/receiver circuit 203 transmits data signals (for example, reference signals and precoded data signals) via the antenna 201 to the UE 10. The transmitter transmits CSI-RS resource information that indicates a state of the determined CSI-RS resources (for example, subframe configuration ID and mapping information) to the UE 20 via higher layer signaling or lower layer signaling. The transmitter transmits the CSI-RS allocated to the determined CSI-RS resources to the UE 10.

The receiver included in the transmitter/receiver circuit 203 receives data signals (for example, reference signals and the CSI feedback information) via the antenna 201 from the UE 10.

The CSI-RS scheduler 203 determines CSI-RS resources allocated to the CSI-RS. For example, the CSI-RS scheduler 203 determines a CSI-RS subframe that includes the CSI-RS in subframes. The CSI-RS scheduler 203 determines at least an RE that may be mapped to the CSI-RS.

The CSI-RS generator 204 generates CSI-RS for estimating the downlink channel states. The CSI-RS generator 204 may generate reference signals defined by the LTE standard, dedicated reference signal (DRS) and Cell-specific Reference Signal (CRS), synchronized signals such as Primary synchronization signal (PSS) and Secondary synchronization signal (SSS), and newly defined signals in addition to CSI-RS.

The call processor 205 determines a precoder applied to the downlink data signals and the downlink reference signals. The precoder may be called a precoding vector or more generally a precoding matrix. The call processor 205 determines the precoding vector (precoding matrix) of the downlink based on the CSI indicating the estimated downlink channel states and the decoded CSI feedback information inputted.

The transmission path interface 206 multiplexes CSI-RS on REs based on the determined CSI-RS resources by the CSI-RS scheduler 203.

The transmitted reference signals may be Cell-specific or UE-specific. For example, the reference signals may be multiplexed on the signal such as PDSCH, and the reference signal may be precoded. Here, by notifying a transmission rank of reference signals to the UE 10, estimation for the channel states may be realized at the suitable rank according to the channel states.

The BS 20 further, in one or more embodiments, comprising hardware configured for reducing feedback overhead associated with bitmap reporting between a user equipment and a base station. For example, the BS 20 may include the capabilities described above for reducing feedback overhead when communicating with the UE 10.

The UE 10 according to one or more embodiments of the present invention will be described below with reference to the FIG. 10.

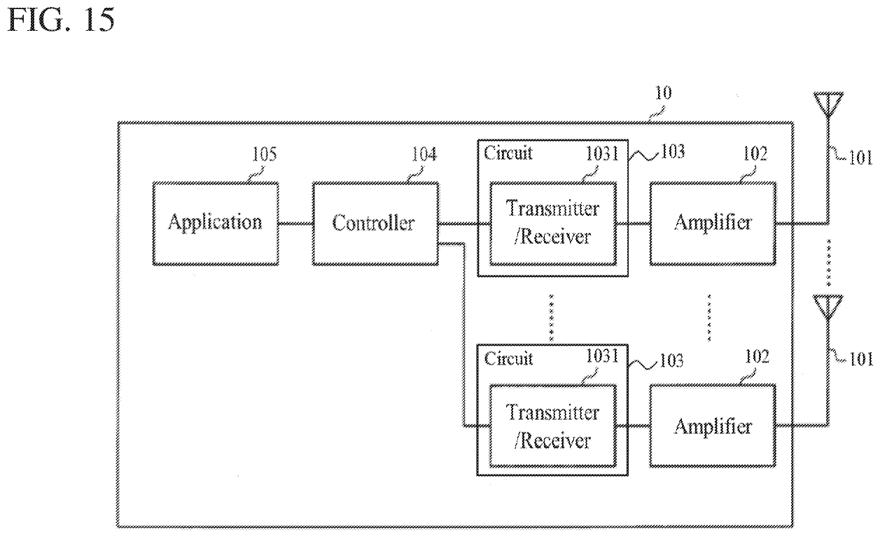

As shown in FIG. 15, the UE 10 may comprise a UE antenna 101 used for communicating with the BS 20, an amplifier 102, a transmitter/receiver circuit 103, a controller 104, the controller including a CSI feedback controller and a codeword generator, and a CSI-RS controller. The transmitter/receiver circuit 103 includes a transmitter and a receiver 1031.

The transmitter included in the transmitter/receiver circuit 103 transmits data signals (for example, reference signals and the CSI feedback information) via the UE antenna 101 to the BS 20.

The receiver included in the transmitter/receiver circuit 103 receives data signals (for example, reference signals such as CSI-RS) via the UE antenna 11 from the BS 20.

The amplifier 102 separates a PDCCH signal from a signal received from the BS 20.

The controller 104 estimates downlink channel states based on the CSI-RS transmitted from the BS 20, and then outputs a CSI feedback controller.

The CSI feedback controller generates the CSI feedback information based on the estimated downlink channel states using the reference signals for estimating downlink channel states. The CSI feedback controller outputs the generated CSI feedback information to the transmitter, and then the transmitter transmits the CSI feedback information to the BS 20. The CSI feedback information may include at least one of Rank Indicator (RI), PMI, CQI, BI and the like.

The CSI-RS controller determines whether the specific user equipment may be the user equipment itself based on the CSI-RS resource information when CSI-RS may be transmitted from the BS 20. When the CSI-RS controller 16 determines that the specific user equipment may be the user equipment itself, the transmitter that CSI feedback based on the CSI-RS to the BS 20.

The UE 10 further, in one or more embodiments, comprising hardware configured for reducing feedback overhead associated with bitmap reporting between a user equipment and a base station. For example, the UE 10 may include the capabilities described above for reducing feedback overhead when communicating with the BS 20.

In one or more embodiments, the UE 10 and the BS 20 have a pre-agreed (in the spec) set of codes. Once the UE 10 selects the rank (which defines B_{Tot}) and the value of number of NZCs, the choice of the code used may be unambiguous. The code may be then used by the UE for encoding. Once the BS 20 receives through feedback (UCI part I) the number of NZCs and the rank (and thus B_{Tot}), it may also know what code to use for decoding. As such, the BS 20 may start decoding and may continue until it decodes exactly B_{Tot} bits.

The above examples and modified examples may be combined with each other, and various features of these examples can be combined with each other in various combinations. The invention may not be limited to the specific combinations disclosed herein.

Although the disclosure has been described with respect to only a limited number of embodiments, those skilled in the art, having benefit of this disclosure, will appreciate that various other embodiments may be devised without departing from the scope of the present invention. Accordingly, the scope of the invention should be limited only by the attached claims.

1. A method for a user equipment in communication with a base station, the method comprising:
initiating a coding scheme for reporting a bitmap associated with a prefix coding scheme;
encoding a plurality of bit groups using the prefix coding scheme;
generating codeword sets for the plurality of bit groups resulting from the encoding; and
reporting, to the base station, the codeword sets generated.

2. The method according to claim 1, further comprising:
dividing the bitmap into a plurality of bit groups, each bit group corresponding to a unique information value in the bitmap;
obtaining a probability value relating to at least one codeword set out of the codeword sets generated; and
using the probability value for selecting at least one codeword set of the generated codeword sets; and
using the at least one codeword set for encoding at least one bit group using the prefix coding scheme.

3. The method according to claim 2, wherein:
the probability value relating to at least one codeword set is obtained from the bitmap.

4. The method according to claim 2, wherein:
in generating the codeword sets based on the probability value of the at least one codeword set, bit groups with a higher probability value are coded with smaller size codewords.

5. The method according to claim 2, wherein, the method further comprising:
assuming that separate codeword sets for one or more respective probability values are predefined.

6. The method according to claim 2, the method further comprising:
assuming that separate codeword sets for one or more respective probability values are predefined based on different bit group information parameters.

7. The method according to claim 1, further comprising:
obtaining a codeword information parameter associated to at least one bit group;
obtaining a probability value of at least one codeword set based on the codeword information parameter;
determining parameters for encoding the plurality of bit groups using the prefix coding scheme based on the probability value for the at least one codeword set; and
feeding back information indicative of the parameters for encoding the plurality of bit groups.

8. The method according to claim 7, wherein:
the codeword information parameter associated to at least one bit group is a number indicative of an amount of Non-Zero Coefficients (NZC) in the bitmap.

9. (canceled)

10. (canceled)

11. (canceled)

12. The method according to claim 1, further comprising:
creating at least one bitmap-to-codeword mapping table; and
encoding the plurality of bit groups using the bitmap-to-codeword mapping tables created; and
reporting the codeword sets generated preceded by a preamble indicator, and, when at least two bitmap-to-codeword mapping tables have been created, the preamble indicator indicating which table out of the bitmap-to-codeword mapping tables is being used.

13. The method according to claim 1, wherein:
the prefix coding scheme is a Huffman coding scheme, and
the feedback overhead associated with bitmap reporting is performed in association with performing Channel State Information (CSI) feedback in a wireless communication system.

14. The method according to claim 1, further comprising:
identifying Non-Zero Coefficients (NZCs) for at least one layer;
obtaining locations for the NZCs identified;
determining a number of NZCs; and
creating the bitmap capturing the NZCs locations obtained and the number of NZCs.

15. The method according to claim 1, further comprising:
evaluating a plurality of bitmaps for a plurality of layers;
determining a size of a joint bitmap, the joint bitmap comprising the plurality of bitmaps for the plurality of layers;
creating the joint bit map comprising the plurality of bitmaps for the plurality of layers; and
the joint bitmap comprising at least one probability value relating to selecting one or more codeword sets.

16. The method according to claim 15, wherein:
the at least one probability value is determined from evaluating the joint bitmap.

17. A user equipment in communication with a base station, comprising:
a receiver that receives bitmap information from a base station;
a processor that:
initiates a coding scheme for reporting a bitmap based on the bitmap information received and associated with a prefix coding scheme;
encodes a plurality of bit groups using the prefix coding scheme;
generates codeword sets for the plurality of bit groups resulting from the encoding; and
a transmitter that transmits the codeword sets generated to the base station.

18. The user equipment according to claim 17, wherein the processor further:
divides the bitmap into a plurality of bit groups, each bit group corresponding to a unique information value in the bitmap;
obtains a probability value relating to at least one codeword set;
uses the probability value for selecting at least one codeword set of the generated codeword sets; and
uses the at least one codeword set for encoding at least one bit group using the prefix coding scheme.

19. The user equipment according to claim 17, wherein the processor further:
obtains a codeword information parameter associated to at least one bit group;
obtains a probability value of at least one codeword set based on the codeword information parameter;
determines parameters for encoding the plurality of bit groups using the prefix coding scheme based on the probability value for the at least one codeword set; and
feeds back information indicative of the parameters for encoding the plurality of bit groups.

20. The user equipment according to claim 19, wherein:
the codeword information parameter associated to at least one bit group is a number indicative of an amount of Non-Zero Coefficients (NZC) in the bitmap.

21. (canceled)

22. (canceled)

23. The user equipment according to claim 17, wherein the processor further:
creates at least one bitmap-to-codeword mapping tables; and
encodes the plurality of bit groups using the bitmap-to-codeword mapping tables created; and
reports the codeword sets generated preceded by a preamble indicator, and, when bitmap-to-codeword mapping tables have been created, the preamble indicator indicating which table out of the bitmap-to-codeword mapping tables is being used.

24. The user equipment according to claim 17, wherein:
the prefix coding scheme being a Huffman coding scheme, and
the feedback overhead associated with bitmap reporting is performed in association with performing Channel State Information (CSI) feedback in a wireless communication system.

25. A method for reducing feedback overhead associated with bitmap reporting between a user equipment and a base station, comprising:
generating, by the base station, a bitmap information, the bitmap information comprising predetermined information relating to at least one code scheme;
selecting, by the user equipment, a rank associated with a bitmap size and a number of Non-Zero Coefficients (NZCs), the rank and the number of NZCs being selected using the bitmap information;
identifying a code scheme for encoding a bitmap based on the rank and the number of NZCs selected;
encoding, by the user equipment, the bitmap using the code scheme identified;
feeding back, by the user equipment, the rank and the number of NZCs selected to the base station; and
decoding, by the base station, the encoded bitmap using the code scheme used by the user equipment, which is identified by the rank and the number of NZCs fed back by the user equipment.
